(19) United States
(12) Patent Application Publication
(10) Pub. No.: US 2026/0324145 A1
(43) Pub. Date: Oct. 15, 2026

(54) MICRO LIGHT EMITTING DIODE CHIP

(71) Applicant: Hue Inc., Shanghai (CN)

(72) Inventors: Zhichen Gu, Shanghai (CN); Weisin Tan, Shanghai (CN)

(73) Assignee: Hue Inc., Shanghai (CN)

(21) Appl. No.: 19/646,429

(22) Filed: Apr. 13, 2026

(30) Foreign Application Priority Data
Apr. 14, 2025 (CN) 202510459681.6

(51) Int. Cl. H10H 20/84; H10H 20/813

(52) U.S. Cl. CPC H10H 20/84; H10H 20/8132

(57) ABSTRACT

A micro-LED chip includes micro-mesas; each micro-mesa includes: a light-emitting layer, and two types of semiconductor layer; a bottom metal layer located at the bottom of the micro-mesa; a bottom dielectric layer with a trench located at the bottom of the bottom metal layer; a first bottom contact hole located in the bottom dielectric layer and located at the bottom of the bottom metal layer, and the first bottom contact hole is in contact with the bottom metal layer; a sidewall dielectric layer located on sidewalls of the micro-mesa and t the bottom metal layer; a top conductive layer continuously covering of the micro-mesa, the sidewall dielectric layer, and the area between adjacent micro-mesas; and a second bottom contact structure located in the trench and within the bottom dielectric layer between adjacent micro-mesas, the second bottom contact structure is not in contact with the bottom metal layer.

### CROSS-REFERENCE TO RELATED APPLICATION

This application claims the priority benefit of China application serial no. 202510459681.6, filed on Apr. 14, 2025. The entirety of the above-mentioned patent application is hereby incorporated by reference herein and made a part of this specification.

### TECHNICAL FIELD

The present disclosure relates to the field of LED technology, and more specifically, relates to a micro light emitting diode chip.

### BACKGROUND

Micro light emitting diode (Micro-LED) technology is a high pixel density LED flat panel display technology using micrometer-level LEDs as pixel elements, and assembled on a control backplane in micrometer-level periodicity. The core structure of the micro-LED is a PN junction diode composed of direct-bandgap semiconductor material. When the upper and lower electrodes apply a forward bias voltage to the micro-LED to allow current to pass through, electrons and holes recombine in the active area, and meanwhile emit monochromatic light photons.

Compared with traditional LEDs, Micro-LEDs have better strain relaxation, better light extraction efficiency, uniform current diffusion, and higher output performance. Micro-LEDs also have advantages such as improved thermal effects, faster response speed, wider operating temperature range, higher resolution, wider color gamut, higher contrast, lower power consumption, and higher current density, etc. Micro-LEDs are hailed as the next generation display technology and are receiving increasing attention.

However, in the future, micro-LED chips will develop toward higher resolution and pixel density to present clearer and more refined images. Nevertheless, when the spacing between micro-LED arrays, i.e., the minimum center distance between micro-LEDs, is less than 3 micrometers, the spacing between adjacent micro-LEDs will become extremely small, which imposes extremely strict requirements on the manufacturing processes for Micro-LED chips.

For example, when dealing with structures with such small spacing, the photoresist performance, exposure dose control, and photolithography equipment accuracy all need to reach the top level. Slight photolithography errors may cause a short-circuit between adjacent micro-LEDs or a deviation in the shape of the light-emitting area, which can seriously affect the display effect. Furthermore, electrode deposition between adjacent micro-LEDs is another challenge, as it is difficult to form electrode layers of the expected shape at such a micro scale.

Therefore, there is a need for a new type of micro-LED chip that can at least partially solve the problems existing in the prior art.

### SUMMARY

In view of some or all of the problems in the prior art, the task of the present disclosure is to provide a micro-LED chip, which includes a micro-mesa array, and the micro-mesa array includes a plurality of micro-mesas; each micro-mesa includes: from bottom to top, a first type semiconductor layer, a light-emitting layer, and a second type semiconductor layer stacked in sequence, and the first type semiconductor layer is different from the second type semiconductor layer; a bottom metal layer located under at least one the micro-mesa; a bottom dielectric layer located under the bottom metal layer, the bottom dielectric layer being provided with at least one trench; a first bottom contact hole located in the bottom dielectric layer and being in contact with a bottom of the bottom metal layer; a sidewall dielectric layer located on a sidewall of the micro-mesa and a sidewall of the bottom metal layer; a top conductive layer continuously covering a top surface of the micro-mesa, a surface of the sidewall dielectric layer, and a region between adjacent micro-mesas; and a second bottom contact structure located in the at least one trench and within the bottom dielectric layer between adjacent micro-mesas, the second bottom contact structure being not in contact with the bottom metal layer.

In some embodiments, a top of the second bottom contact structure is lower than the bottom of the bottom metal layer, and the top of the second bottom contact structure is lower than a top of the trench.

In some embodiments, a transverse width of the second bottom contact structure is less than a transverse width of a gap between adjacent bottom metal layers.

In some embodiments, the top conductive layer further covers a top surface of the second bottom contact structure.

In some embodiments, a plurality of the second bottom contact structures are integrally connected with each other.

In some embodiments, the plurality of second bottom contact structures are arranged in a crisscross interconnected pattern and disposed around the first bottom contact hole below each micro-mesa, the at least one trench is also arranged in a crisscross interconnected pattern and disposed in the bottom dielectric layer and located around the first bottom contact hole below each micro-mesa.

In some embodiments, the top conductive layer contacts a top surface of the second bottom contact structure at least at one crisscross intersection of the second bottom contact structures.

In some embodiments, the first bottom contact hole and the second bottom contact structure are arranged at intervals.

In some embodiments, a spacing between sidewalls of the trench located above the second bottom contact structure is greater than the spacing between the sidewalls of the trench in contact with the second bottom contact structure.

In some embodiments, a material of the first bottom contact hole is metal; a material of the second bottom contact structure is metal.

In some embodiments, the metal includes one or more of copper, gold, tin, platinum, tungsten, chromium, rhodium, titanium, silver, germanium, or nickel.

In some embodiments, the sidewall dielectric layer covers the entire sidewall of the micro-mesa and covers the entire sidewall of the bottom metal layer, leaving an aperture at a top of the micro-mesa; and the aperture exposes part or all of the top of the micro-mesa.

In some embodiments, a material of the sidewall dielectric layer is one or more of silicon oxide, silicon oxynitride, or silicon nitride.

In some embodiments, the bottom of the first type semiconductor layer also has a bottom conductive layer; the bottom metal layer is located at the bottom of the bottom conductive layer; the light-emitting layer is a multilayer stack; the first type semiconductor layer is N-type and the second type semiconductor layer is P-type; or, the first type semiconductor layer is P-type and the second type semiconductor layer is N-type.

In some embodiments, the micro-LED chip further includes a reflective layer, the reflective layer is located between the bottom conductive layer and the first bottom contact hole, and located between the second bottom contact structure and the top conductive layer, respectively, and a top area of the reflective layer is substantially the same as a top area of the first bottom contact hole and the second bottom contact structure.

In some embodiments, a material of the bottom metal layer is one or more of the following metals or an alloy thereof: Cr, Al, Ti, Ni, Pt, Au, or Sn;

a material of the bottom conductive layer is one or a combination of graphene, indium tin oxide, aluminum-doped zinc oxide, or fluorine-doped tin oxide; and

a material of the top conductive layer is one or a combination of graphene, indium tin oxide, aluminum-doped zinc oxide, or fluorine-doped tin oxide.

In some embodiments, a top of the second type semiconductor layer includes a metal island layer; and the metal island layer includes a plurality of mutually isolated metal particles.

In some embodiments, the micro-LED chip further includes a drive backplane, the drive backplane includes at least one drive circuit, and the at least one drive circuit is electrically connected with each first bottom contact hole in the micro-mesa array.

In some embodiments, the sidewall of the micro-mesa is provided with a step, and the step includes a flat portion located on a sidewall of the second type semiconductor layer.

In some embodiments, the sidewall of the micro-mesa is inclined, with an inclination angle range of 60° to 85°.

The technical solution provided by the present disclosure has the following beneficial effects:
1. The first bottom contact hole of the micro-LED structure provided by the present disclosure is electrically connected with the first type semiconductor layer of the micro-mesa through the bottom metal layer and the bottom conductive layer, and the second bottom contact structure is electrically connected with the second type semiconductor layer of the micro-mesa through the top conductive layer. The first bottom contact hole and the second bottom contact structure, serving as the positive and negative electrodes of the micro-LED, are both arranged within the bottom dielectric layer below the micro-mesa. The bottom dielectric layer is located on the top surface of the drive backplane. The first bottom contact hole is electrically connected with the drive circuit within the drive backplane, and the second bottom contact structure is led out at the edge of the micro-mesa array and electrically connected with external pads. Embedding the second bottom contact structure as the top electrode of the micro-LED within the bottom dielectric layer of the drive backplane can prevent the second bottom contact structure from blocking the micro-mesa, thereby increasing the light extraction efficiency.
2. The structure proposed by the present disclosure eliminates the arrangement of top electrodes on the side surface of the micro-mesa. The light absorption effect of the top electrode on the side surface is reduced, and the beam collimation effect of the microlens is improved.
3. The micro-LED structure provided by the present disclosure improves the microlens by improving the contour of the microlens to adjust the height of the lower spacer, curvature radius, and lens spherical height, the micro defects of the lens can be improved, thereby further enhancing the brightness or luminous efficiency of the micro-LED chip. The specific technical effects are as follows: the benefit of increasing the height of the lower spacer particularly lies in: under the premise of determining the curvature radius, the light source mainly radiates from the top of the pixel, and increasing the curvature radius raises the height of the lower spacer, resulting in an increase in the light emission radius and a decrease in the emission angle at the interface between the same point light source microlens and the air, thereby increasing the light emission angle; the smaller the curvature radius, i.e., the larger the spherical width of the microlens, which is conducive to light emission, correspondingly, the increase in spherical height, i.e., changes the spherical height of the original hemispherical shape of the microlens, which also allows escaping light to exit from the microlens, by changing the curvature, the total emission angle of the microlens is increased, making it difficult to form total reflection light, which is beneficial for the light extraction effect.

### BRIEF DESCRIPTION OF THE DRAWINGS

The present disclosure is further explained with reference to the accompanying drawings in conjunction with specific implementations below.

FIG. 1 illustrates a schematic top view of a micro-LED chip according to an embodiment of the present disclosure.

FIG. 2 illustrates a schematic longitudinal sectional view along line AA of the micro-LED chip according to an embodiment of the present disclosure.

FIG. 3 illustrates a schematic top view of a first bottom contact hole 111 and a second bottom contact structure 112 according to an embodiment of the present disclosure.

FIG. 4 illustrates a schematic longitudinal sectional view of a micro-LED chip according to an embodiment of the present disclosure.

FIG. 5 illustrates a schematic longitudinal sectional view of a micro-LED chip according to an embodiment of the present disclosure.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same accompanying drawing reference numerals.

In the present disclosure, unless otherwise specified, the words "arranged on", "arranged above" and "arranged over" do not exclude the existence of intermediates between the two. Furthermore, "arranged on or above" merely indicates the relative positional relationship between the two components, but under certain circumstances, such as when the product direction is reversed, it can be converted to "arranged under or below", and vice versa.

In the present disclosure, the embodiments are merely intended to illustrate the scheme of the present disclosure and should not be construed as limiting.

In the present disclosure, the quantifiers "a" and "one" do not exclude scenarios with a plurality of elements, unless otherwise specified.

In the present disclosure, the term "connect" may refer to both a direct connection between two elements and an indirect connection between two elements via an intermediate component.

In the present disclosure, the term "configure" refers to the setting of the shape, structure, material, and/or function of a target object to achieve a desired technical effect, and "configure" includes various alternative technical means to achieve this technical effect, and these technical means become apparent under the teachings of the present disclosure.

It should also be noted herein that in embodiments of the present disclosure, merely a part of the components or assemblies may be shown for the sake of clarity and simplicity, but those ordinary skilled in the art will be able to understand that the required components or assemblies may be added as needed according to specific scenarios in light of the teachings of the present disclosure. Furthermore, features in different embodiments of the present disclosure may be combined with each other unless otherwise indicated. For example, a certain feature in the second embodiment may be used to replace a corresponding or functionally identical or similar feature in the first embodiment, and the obtained embodiment likewise falls within the scope of the disclosure or the scope of the record of the present application.

It should also be noted that, within the scope of the present disclosure, the terms "the same", "equal", "equal to", etc. do not mean that the two numerical values are absolutely equal, but rather allow for a certain reasonable error, that is to say, the terms also cover "substantially the same ", "substantially equal " and "substantially equal to". By analogy, in the present disclosure, the terms "perpendicular to", "parallel to", etc., which indicate direction, also cover the meaning of "substantially perpendicular to", "substantially parallel to".

In the present disclosure, the term "located at the bottom of the micro-mesa" refers to the side of the micro-mesa facing away from the microlens, the term "located at the top of the micro-mesa" refers to the side of the micro-mesa facing the microlens, and the term "side surface of the micro-mesa" refers to the two sides between the top and bottom.

In the present disclosure, the term "contour of the metal layer" refers to the maximum dimension, such as the length, within a plane (or a plane perpendicular to the thickness) defined by the length and width of the metal layer. Similarly, the bottom contour of the micro-mesa refers to the maximum dimension, such as the length, within the bottom plane (i.e., the plane perpendicular to the thickness at the bottom) of the micro-mesa.

The technical solutions in the embodiments of the present disclosure are described clearly and completely below in conjunction with the accompanying drawings in the embodiments of the present disclosure.

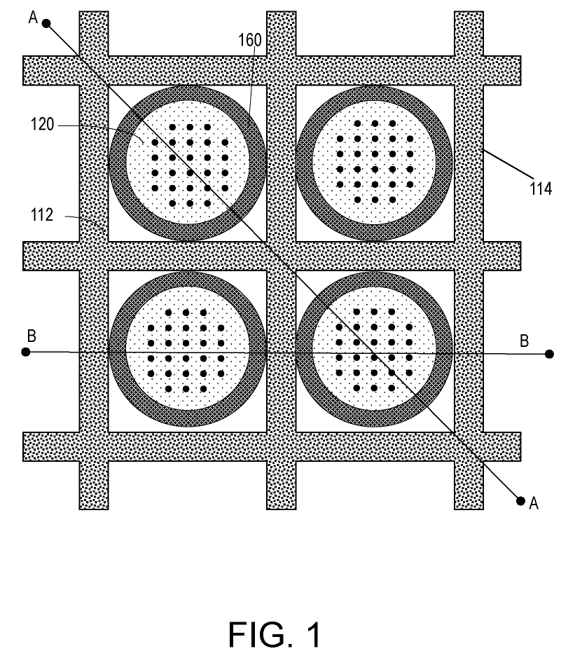

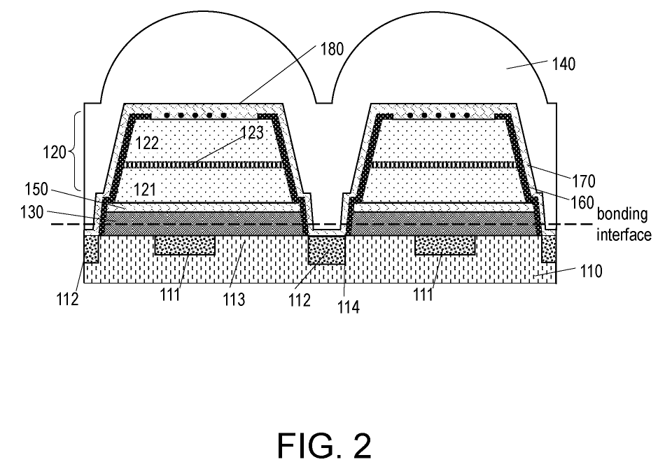

FIG. 1 illustrates a schematic top view of a micro-LED chip according to an embodiment of the present disclosure. FIG. 1 illustrates a plurality of micro-LEDs. FIG. 2 illustrates a schematic longitudinal sectional view along line A-A of the micro-LED chip according to an embodiment of the present disclosure. As shown in the figures, the micro-LED chip includes a drive backplane 110, at least one micro-LED, a bottom metal layer 130, and at least one microlens 140. The micro-LED is arranged on the upper surface of the drive backplane 110. The bottom metal layer 130 is located between the drive backplane and the micro-LED. The microlens 140 is arranged on the upper surface of the micro-LED, and adjacent microlenses 140 between micro-LEDs are separated. In some embodiments of the present disclosure, a drive module includes the drive backplane 110.

The micro-LED includes: a bottom conductive layer 150, a micro-mesa 120, a sidewall dielectric layer 160, and a top conductive layer 170. One or more micro-LEDs are arranged on the upper surface of the drive backplane 110. The upper surface of the drive backplane 110 includes a first bottom contact hole 111, a second bottom contact structure 112, and a bottom dielectric layer 113 surrounding the first bottom contact hole 111 and the second bottom contact structure 112. The first bottom contact hole 111 is located at the bottom of the bottom metal layer 130, and the first bottom contact hole 111 is in contact with the bottom metal layer 130 to form an electrical connection. The bottom metal layer 130 is electrically connected with the bottom conductive layer 150, and the bottom conductive layer 150 is arranged at the bottom of the micro-mesa 120. The second bottom contact structure 112 is located within a trench 114 and in the bottom dielectric layer 113 between adjacent micro-mesas 120, and is not in contact with the bottom metal layer 130.

The size of each micro-LED chip does not exceed 1 centimeter, preferably not exceeding 5 millimeters. The micro-LED structures are formed in the form of an array in the micro-LED chip, and with resolutions such as 720*480, 640*480, 1920*1080, 1280*720, 2K, or 4K. The diameters of the micro-LED structures are in the nanometer-level, for example, 20 nm to 100 nm. Each micro-LED may form at least a part of a pixel element on the micro-LED chip.

Introduction to the drive backplane 110:

For convenience, "upward" is used to indicate away from the drive backplane 110, "downward" indicates facing the drive backplane 110, and other directional terms such as top, bottom, above, below, directly below, underneath, etc., are also explained accordingly. In some embodiments of the present disclosure, the drive backplane 110 includes a substrate (not shown in the figure), at least one drive circuit (not shown in the figure), a first bottom contact hole 111, a second bottom contact structure 112, and a bottom dielectric layer 113 surrounding the first bottom contact hole 111 and the second bottom contact structure 112. The first bottom contact hole 111 may also be referred to as a drive electrode of the drive circuit.

In some embodiments of the present disclosure, the substrate is a Si substrate. In other embodiments of the present disclosure, the substrate is a transparent substrate, such as a glass substrate. Examples of other substrates include GaAs, GaP, InP, SiC, ZnO, and sapphire substrates. In some embodiments, the substrate is approximately 700 micrometers thick.

The drive circuit forms individual pixel drivers to control the operation of each individual micro-LED pixel. The drive circuit includes, for example, complementary metal oxide semiconductor (CMOS) devices or TFT devices, etc.

Each first bottom contact hole 111 corresponds to a micro-LED, and each first bottom contact hole 111 is electrically connected with the bottom metal layer 130. In some embodiments of the present disclosure, the material of the first bottom contact hole 111 is one or more of the following metals or an alloy thereof: Ni, Al, Ti, Cu, Sn, W, Cr, Pt, and Au.

In some embodiments of the present disclosure, first, a light-emitting epitaxial layer structure of the micro-LED is fabricated on the surface of the epitaxial substrate. Then, the light-emitting epitaxial layer structure of the micro-LED can be bonded to the surface of the drive backplane 110 through the bottom metal layer 130, and the bonding between the drive backplane 110 and the micro-LED can be achieved through high-temperature, high-pressure bonding methods such as eutectic bonding, hot press bonding, and transient liquid phase (TLP) bonding, etc.

Introduction to the bottom metal layer 130:

In some embodiments of the present disclosure, the bottom metal layer 130 may be provided on the drive backplane 110. In other embodiments of the present disclosure, the bottom metal layer 130 is grown on the drive backplane 110. In some embodiments of the present disclosure, the thickness of the bottom metal layer 130 is 0.1 micrometers to 3 micrometers. In a preferred embodiment, the thickness of the bottom metal layer 130 is 0.6 micrometers. In some embodiments of the present disclosure, the bottom metal layer 130 includes a first metal layer (not shown in the figure) and a second metal layer (not shown in the figure). The first metal layer is in direct contact with the bottom conductive layer 150 at the bottom of the micro-mesa 120, and the second metal layer is located at the bottom layer of the bottom metal layer 130. In some embodiments of the present disclosure, one or more third metal layers are further provided between the first metal layer and the second metal layer. By making the bottom metal layer 130 have multiple metal layers, first, the total thickness of the bottom metal layer 130 can be flexibly controlled by depositing multiple metal layers multiple times during the manufacturing process; secondly, the material selection for each metal layer is also more flexible, for example, the first metal layer in direct contact with the bottom of the bottom conductive layer 150 may be selected from metallic materials that do not easily diffuse into the bottom conductive layer 150 or will not cause serious consequences even if diffusion occurs, or metallic materials with lower contact resistance with the bottom conductive layer 150. The intermediate layer may be selected from metallic materials with good conductivity, and the second metal layer at the bottom may be selected from metallic materials with good bonding properties with the drive backplane 110. In some embodiments of the present disclosure, the material of the first metal layer is one or more of the following metals or an alloy thereof: Cr, Al, Ti, Ni, Pt, Au, and Sn; and/or the material of the second metal layer is one or more of the following metals or an alloy thereof: Cr, Al, Ti, Ni, Pt, Au, and Sn; and/or the material of the third metal layer is one or more of the following metals or an alloy thereof: Cr, Al, Ti, Ni, Pt, Au, and Sn. In some embodiments, the bottom metal layer 130 may also be used as a reflector to reflect light emitted from the LED structure above.

In one embodiment of the present disclosure, after bonding is completed, the epitaxial substrate may be removed through laser stripping. The material of the epitaxial substrate may be sapphire or silicon. The corresponding stripping process may be selected based on the material of the epitaxial substrate. After removing the epitaxial substrate, the epitaxial light-emitting structure may be transferred onto the drive backplane 110. After removal of the epitaxial substrate, the epitaxial buffer layer structure may be further thinned to facilitate the subsequent process of a PN step for epitaxial structure.

In one embodiment of the present disclosure, after bonding is completed, the light-emitting epitaxial layer is etched to form micro-mesas 120. By adjusting the photolithography morphology and ion etching, micro-LED pixels with a positive trapezoidal structure are formed.

As shown in FIG. 2, in some embodiments, the drive backplane 110 may use an integrated circuit (IC) board. The micro-LEDs are electrically connected with the drive backplane 110, and the drive backplane 110 is used to control the turning-on and -off of the micro-LEDs. In some embodiments, the integrated circuit board may be electrically connected with each micro-LED in the micro-LED array through individual metal interconnections. In some embodiments, each micro-LED may be individually electrically controlled by the integrated circuit board. In some embodiments, the integrated circuit board may be electrically connected with the first bottom contact hole 111 through metal interconnections. In some embodiments, a dielectric layer may be formed in the gaps between the micro-LEDs. In some embodiments, the dielectric layer may also be formed in the gaps between the interconnections.

In some embodiments, the micro-LED chip includes a plurality of micro-LED arrays, and each micro-LED array includes a plurality of micro-LEDs. The drive method of the micro-LEDs is, for example, a passive matrix (PM) drive, and the cathodes of all micro-LEDs of each array are connected together to a cathode line NL, while micro-LEDs of the same number of each array are connected to corresponding anode lines PL, respectively. Thus, the on/off and brightness of each micro-LED can be individually controlled by controlling the signal on the corresponding cathode and anode.

In some embodiments, the micro-LEDs may be arranged in a regular or irregular manner on the upper surface of the drive module as pixels of the micro-LED chip. In the micro-LEDs, the bottom conductive layer 150 is located at the bottom of the micro-mesa 120, and the bottom conductive layer 150 is electrically connected with the bottom metal layer 130. The top conductive layer 170 is located on the side surface and top surface of the micro-mesa 120, and the top conductive layer 170 is electrically connected with the second bottom contact structure 112.

In some embodiments, the sidewall dielectric layer 160 at least partially covers the sidewall of the micro-mesa 120 and the sidewall of the bottom metal layer 130, and the sidewall dielectric layer 160 is located between the micro-mesa 120 and the top conductive layer 170. In some embodiments, the sidewall dielectric layer 160 may cover a part of the top surface of the micro-mesa 120. In some embodiments, materials such as silicon dioxide, silicon nitride, silicon oxide, or silicon oxynitride, etc., are deposited as the sidewall dielectric layer using plasma chemical vapor deposition or atomic layer deposition processes. A photolithographic aperture process is performed on the top surface of the micro-mesa 120 for the sidewall dielectric layer 160 through a photolithography process, and at least a part of the surface of the top surface of the micro-mesa 120 is exposed by etching, and the electrical contact between the micro-mesa 120 and the top conductive layer 170 is achieved through the aperture in the sidewall dielectric layer. In some embodiments of the present disclosure, adjacent sidewall dielectric layers are connected, and all sidewall dielectric layers are connected as a whole. In some embodiments of the present disclosure, the material of the sidewall dielectric layer is one or more of silicon oxide, silicon oxynitride, and silicon nitride.

In some embodiments, the electrode polarity of the bottom conductive layer 150 is opposite to the electrode polarity of the top conductive layer 170, the bottom conductive layer 150 may be, for example, a P electrode or an anode electrode, and the top conductive layer 170 is an electrode with opposite polarity to the bottom conductive layer 150, for example, an N electrode or a cathode electrode. In some embodiments of the present disclosure, the bottom conductive layer 150, the top conductive layer 170, and their connecting components may be one or a combination of, such as graphene, or indium tin oxide (ITO), or aluminum-doped zinc oxide (AZO), or fluorine-doped tin oxide (FTO), or other transparent conductive oxides (TCOs).

In some embodiments of the present disclosure, the top conductive layer 170 may be formed on the top surface of the micro-mesa 120 and the top surface of the sidewall dielectric layer 160 using a sputtering process.

In some embodiments of the present disclosure, adjacent top conductive layers 170 are connected, and top conductive layers 170 are connected as a whole. In some embodiments of the present disclosure, the top conductive layer 170 is a full-surface transparent electrode for the display area, and may be formed of a conductive material such as indium tin oxide (ITO). In some embodiments of the present disclosure, the top conductive layer 170 may be formed using processes such as sputtering or electron beam evaporation.

In some embodiments, the top conductive layer 170 may be shared by all micro-LEDs in the micro-LED array.

In some embodiments, the top conductive layer 170 is electrically connected with the second bottom contact structure 112. In some embodiments, a plurality of second bottom contact structures 112 are connected with each other as a whole. The second bottom contact structure 112 may be used as a common electrode connected with each micro-mesa in the micro-LED array. The second bottom contact structure 112 may electrically connect the second type semiconductor layer 122 of the micro-mesa 120 with the negative electrode of an external power source. The second bottom contact structure 112 may also be referred to as an N electrode.

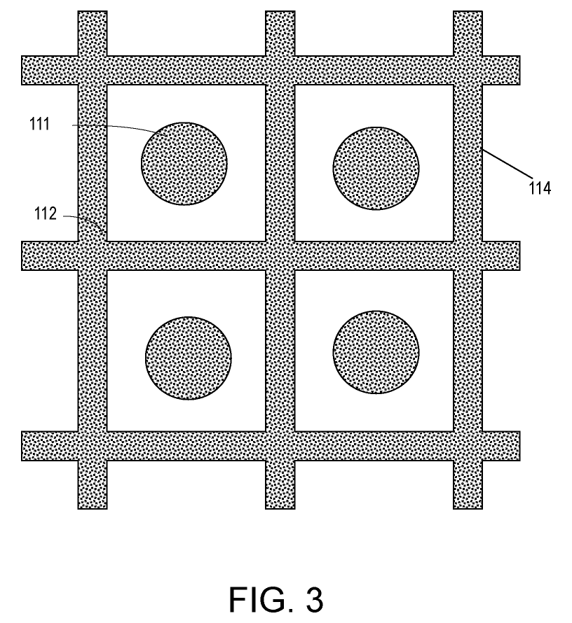

In some embodiments, the second bottom contact structure 112 is located within a trench 114 in the bottom dielectric layer 113. FIG. 3 illustrates a schematic top view of a first bottom contact hole 111 and a second bottom contact structure 112 according to an embodiment of the present disclosure. As shown in FIG. 3, the first bottom contact hole 111 and the second bottom contact structure 112 are arranged at intervals. The second bottom contact structure 112 is strip-shaped, arranged in a crisscross interconnected pattern, and disposed around the first bottom contact hole 111 below the micro-mesas, and the trenches 114 are also arranged in a crisscross interconnected pattern, and disposed in the bottom dielectric layer 113 and located around the first bottom contact hole 111 below each micro-mesa 120. In some embodiments, the second bottom contact structure 112 extends below the micro-mesa and is led out at the edge of the micro-mesa array for electrical connection with external pads. In some embodiments, the material of the first bottom contact hole 111 is metal, and the material of the second bottom contact structure 112 is metal, for example, the metal is one or more of copper, gold, tin, platinum, tungsten, chromium, rhodium, titanium, silver, germanium, or nickel.

In some embodiments, the top conductive layer 170 covers at least a part of the top surface of the second bottom contact structure 112. To prevent short-circuiting between the first type semiconductor layer 121 and the second type semiconductor layer 122 of the micro-mesa 120, the second bottom contact structure 112 cannot contact the bottom metal layer 130. The transversal width of the second bottom contact structure 112 may be made smaller than the transversal width of the gap between adjacent bottom metal layers 130, thereby preventing the bottom surface of the bottom metal layer 130 from contacting the top surface of the second bottom contact structure 112.

As can be seen from FIG. 1, the spacing between the micro-mesas is the smallest along the direction of the B-B line, whereas it is the largest along the direction of the A-A line. In some embodiments, the top conductive layer 170 contacts the second bottom contact structure 112 only above the cross points of the second bottom contact structure 112. The top of the other areas of the second bottom contact structure 112 is covered by the bottom dielectric layer 113. The advantage of this structure is that it can reduce the difficulty of the process and avoid etching and deposition of the top conductive layer in small-sized gaps. However, those skilled in the art should understand that in the above embodiments, the contact position between the top conductive layer 170 and the second bottom contact structure 112 is shown for illustrative purposes only and is non-limiting. In other embodiments of the present disclosure, the top conductive layer 170 may contact the top surface of the second bottom contact structure 112 at any suitable position.

In some embodiments of the present disclosure, the micro-mesa 120 may be a trapezoidal mesa, and the transverse dimension of the bottom of the micro-mesa 120 is greater than the transverse dimension of the top. In some embodiments of the present disclosure, the inclination angle range of the sidewall of the micro-mesa 120 is between 60° and 85°. In some embodiments of the present disclosure, the transverse dimension of the bottom of the micro-mesa 120 does not exceed 3 micrometers. In some embodiments of the present disclosure, the transverse dimension of the top of the micro-mesa 120 does not exceed 1.5 micrometers. In some embodiments of the present disclosure, the transverse dimensions of the bottom conductive layer 150 and the bottom metal layer 130 are larger than the transverse dimension of the bottom of the micro-mesa 120.

As shown in FIG. 2, the micro-mesa 120 includes a first type semiconductor layer 121, a second type semiconductor layer 122, and a light-emitting layer 123 located between the first type semiconductor layer 121 and the second type semiconductor layer 122. The first type semiconductor layer 121 is electrically connected with the bottom conductive layer 150. The second type semiconductor layer 122 is electrically connected with the top conductive layer 170. In some embodiments, the micro-mesa 120 of each micro-LED in the micro-LED array may be a micrometer-level micro-mesa 120. In some embodiments, the micrometer-level micro-mesa 120 may include, from bottom to top, a first type semiconductor layer 121, a light-emitting layer 123, and a second type semiconductor layer 122. That is, in the three-layer structure, the first type semiconductor layer 121 is closest to the drive backplane 110; the light-emitting layer 123 is located above the first type semiconductor layer 121 and farther away from the drive backplane 110; and the second type semiconductor layer 122 is located above the light-emitting layer 123 and farthest away from the drive backplane 110. In some embodiments, the light-emitting layer 123 is formed by multiple stacked quantum well layers, particularly superlattice-stacked quantum well layers. Preferably, the superlattice-stacked quantum well layers include multiple pairs of quantum well layers stacked with quantum barrier layers. In some embodiments, the first type semiconductor layer 121 is a semiconductor material with a first conductivity type and includes a plurality of semiconductor layers. The primary matrix material of the first type semiconductor layer may be, but is not limited to, materials such as Ga, N, As, P, In, or Al, etc. Furthermore, the first type semiconductor layer 121 may include, from top to bottom, but is not limited to, a waveguide layer, a confinement layer, a transition layer, and a window layer; furthermore, a bottom conductive layer 150 may be formed below the window layer. In some embodiments, the second type semiconductor layer 122 is a semiconductor material with a second conductivity type and includes a plurality of semiconductor layers. The primary matrix material of the second type semiconductor layer 122 may include, but is not limited to, materials such as Ga, N, As, P, In, or Al, etc. Furthermore, the second type semiconductor layer 122 may include, from top to bottom, but is not limited to, a confinement layer and a waveguide layer; furthermore, in some embodiments, a top conductive layer 170 may be formed on the confinement layer. In some embodiments of the present disclosure, the first conductivity type is different from the second conductivity type.

In some embodiments, the first type semiconductor layer 121 is an N-type GaN layer or an N-type AlGaN layer, and the second type semiconductor layer 122 is a P-type GaN layer or a P-type AlGaN layer. That is, the material of the second type semiconductor layer 122 may be a material layer of a second conductivity type including at least two or more elements of Ga, N, As, Al, In, and P, and the first type semiconductor layer 121 may be a material layer of a first conductivity type including at least two or more elements of Ga, N, As, Al, In, and P. In some embodiments, the light-emitting layer 123 includes a multi-quantum-well layer and an electron blocking layer, and the multi-quantum-well layer is an InGaN/GaN multi-quantum-well layer, or an InGaN/AlGaN multi-quantum-well layer, or an InGaAs/AlGaAs multi-quantum-well layer. In some embodiments, the light-emitting layer 123 further includes an electron blocking layer, and the electron blocking layer is located on a first side of the light-emitting layer 123, and the first side refers to the side along which electrons migrate out of the light-emitting layer 123. In other embodiments of the present disclosure, the first type semiconductor layer 121 may also be a P-type GaN layer or a P-type AlGaN layer, and the second type semiconductor layer 122 may be an N-type GaN layer or an N-type AlGaN layer.

In some embodiments, the light-emitting layer 123 includes at least one quantum well layer (not shown in the figure). The thickness of the quantum well layer is between 20 nm and 40 nm, for example, the thickness is 30 nm. In some embodiments, the material of the quantum well layer is GaInP/(AlₓGa₁₋ₓ)_{y}In_{1-y}P, and the range of x is 0.5 to 0.9, and the range of y is 0.3 to 0.5. For example, x is 0.8 and y is 0.5. In some embodiments, the relationship between x and y is that x is 1 to 2 times y.

In some embodiments, one of the first type semiconductor layer 121 and the second type semiconductor layer 122 is an N-type semiconductor layer, and the other is a P-type semiconductor layer. In some embodiments, the N-type semiconductor layer also includes a doped N-type contact layer and an N-type cladding layer, and the N-type cladding layer is formed on the doped N-type contact layer. The material of the N-type cladding layer is AlₓIn₁₋ₓP, and the range of x is 0.1 to 0.5, for example, x is 0.5. Furthermore, in these embodiments, the thickness of the N-type cladding layer is not greater than 350 nm, for example, the thickness of the N-type cladding layer is 320 nm. The doping concentration of the N-type cladding layer is 5e¹⁷cm⁻³ to 1e¹⁸cm⁻³. The material of the doped N-type contact layer is GaAs. In some embodiments, the thickness of the doped N-type contact layer is 10 nm to 30 nm. In some embodiments, the doping concentration of the doped N-type contact layer is 2e¹⁸cm⁻³ to 1e¹⁹cm⁻³. In some embodiments, the N-type semiconductor layer also includes an N-type spacer layer formed on the N-type cladding layer. The material of the N-type spacer layer is (AlₓGa₁₋ₓ)_{y}In_{1-y}P, and the range of x is 0.5 to 0.9, and the range of y is 0.1 to 0.5. For example, x is 0.8 and y is 0.5. In some embodiments, the relationship between x and y is that x is 1 to 2 times y. The thickness of the N-type spacer layer is 50 nm to 75 nm, for example, 65 nm.

In some embodiments, the P-type semiconductor layer includes a P-type cladding layer and a doped P-type contact layer. The P-type cladding layer is formed on the light-emitting layer 123, and the doped P-type contact layer is formed on the P-type cladding layer. In some embodiments, the material of the P-type cladding layer is AlₓIn₁₋ₓP, and x is 0.3 to 0.5, for example, x is 0.5. In such embodiments, the thickness of the P-type cladding layer is not greater than 380 nm, for example, the thickness of the P-type cladding layer is 360 nm. In some embodiments, the material of the doped P-type contact layer is GaAs. The thickness of the doped P-type contact layer is 10 nm to 30 nm, for example, 20 nm.

In some embodiments, the P-type semiconductor layer also includes a P-type spacer layer formed below the P-type cladding layer, a first doped P-type transition layer formed on the P-type cladding layer, and a second doped P-type transition layer formed on the first doped P-type transition layer. In some embodiments, the material of the P-type spacer layer is (AlₓGa₁₋ₓ)_{y}In_{1-y}P, and the range of x is 0.5 to 0.9, and the range of y is 0.3 to 0.5. For example, x is 0.8 and y is 0.5. In some embodiments, the relationship between x and y is that x is 1 to 2 times y. In some embodiments, the thickness of the P-type spacer layer is 50 nm to 75 nm, for example, 65 nm.

In some embodiments, the material of the first doped P-type transition layer is (AlₓGa₁₋ₓ)_{y}In_{1-y}P, and the range of x is 0.1 to 0.3, and the range of y is 0.3 to 0.5. For example, x is 0.17 and y is 0.5. In some embodiments, the relationship between x and y is that y is 1 to 5 times x. In some implementations, the thickness of the first doped P-type transition layer is 20 nm to 40 nm, for example, 30 nm.

In some embodiments, the material of the second doped P-type transition layer is AlₓGa₁₋ₓAs, and the range of x is 0.5 to 0.9, for example, x is 0.6. In some embodiments, the thickness of the second doped P-type transition layer is 10 nm to 30 nm, for example, 20 nm.

In some embodiments, the doping concentration of the second doped P-type transition layer is greater than the doping concentration of the first doped P-type transition layer. The doping concentration of the doped P-type contact layer is 1 to 10 times that of the second doped P-type transition layer.

In some embodiments, the doping concentration of the doped P-type contact layer is greater than the doping concentration of the second doped P-type transition layer. Furthermore, in some embodiments, the doping concentration of the second doped P-type transition layer is 2 to 4 times that of the first doped P-type transition layer.

For example, the doping concentration of the first doped P-type transition layer is greater than 1e¹⁸cm⁻³, the doping concentration of the second doped P-type transition layer is in the range of 2e¹⁸cm⁻³ to 4e¹⁸cm⁻³, and the doping concentration of the doped P-type contact layer is greater than 5e¹⁸cm⁻³.

In FIG. 2, the transverse dimension of the bottom of the microlens 140 is greater than the transverse dimension of the light-emitting area of the micro-LED. In some embodiments, the transverse dimension of the bottom surface of the microlens 140 may be equal to the transverse dimension of the light-emitting area of the micro-LED.

In some embodiments, a microlens 140 may cover a plurality of lens less micro-LEDs. A plurality of microlenses form a microlens array. The microlens array is arranged above the micro-LED array, and at least one microlens is provided on the surface of the top conductive layer of the micro-LED, and the horizontal contour of the microlens is larger than the maximum horizontal contour of the micro-LED. The microlens primarily serves to converge and/or collimate light. For example, by adjusting parameters such as the thickness and curvature of the microlens, etc., the focal point of the microlens can be located in the micro-mesa 120 of the micro-LED. Microlenses in a microlens array are typically the same. Examples of microlenses include spherical microlenses, non-spherical microlenses, Fresnel microlenses, and cylindrical microlenses. As shown in FIG. 2, in some embodiments of the present disclosure, the microlens 140 includes an upper curvature portion and a lower spacer portion. In some embodiments of the present disclosure, typical shapes for the lower spacer portion of each microlens 140 include circles, squares, rectangles, and hexagons. Each microlens in the microlens array of the display panel may be the same or different in shape, curvature, optical power, size, base, spacer, and other aspects.

In some embodiments of the present disclosure, the curvature centers at various positions of the sidewall of the lower spacer do not coincide with the curvature centers at various positions of the upper curvature portion. The thickness of the lower spacer is set such that the focal point of the microlens is located in the micro-mesa 120 of the micro-LED. In some embodiments of the present disclosure, the height of the lower spacer portion of the microlens is 0.5 to 3 micrometers, and/or the height of the upper curvature portion of the microlens is 0.5 to 2 micrometers, and/or the spherical width of the microlens is 3 to 4 micrometers. In another embodiment, the microlens may, for example, be hemispherical shape.

In some embodiments, the shape of the microlens 140 may be a curved hemispherical shape. In some embodiments, the height of the microlens 140 is not greater than 2 micrometers. In some embodiments, the height of the microlens 140 is not greater than 1 micrometer. In some embodiments, the height of the microlens 140 is not greater than 0.5 micrometers. In some embodiments, the width of the microlens 140 is not greater than 4 micrometers. In some embodiments, the width of the microlens 140 is not greater than 3 micrometers. In some embodiments, the width of the microlens 140 is not greater than 2 micrometers. In some embodiments, the width of the microlens 140 is not greater than 1 micrometer. In some embodiments, the width to height ratio of the microlens 140 is greater than 1.5.

In some embodiments, the microlens 140 may be made of various materials that are transparent to light of various wavelengths emitted by the micro-LED. Exemplary transparent materials for the microlens 140 include polymers and dielectric materials. In some embodiments, dielectric materials include one or more materials such as silicon dioxide, silicon nitride, silicon carbide, titanium dioxide, zirconium dioxide, aluminum oxide, etc. In some embodiments, the microlens 140 is made of photoresist.

In some embodiments, the manufacturing process for microlens 140 is mainly based on CVD deposition of a SiO₂ film layer. Due to the actual deposited film thickness varying between 2.5 and 4 μm, the deposition procedure used is generally a high deposition rate film formation method. Consequently, deposition defects such as microcracks may occur in deep trench areas. After the deposition is completed, a photoresist with suitable viscosity, for example, positive photoresist, etc., is selected to perform wafer surface coating, then, the light shielding area of the exposed photoresist plate is arranged to coincide with the pixel point position, and then exposed to form the photolithography pattern of the microlens 140, and the morphology of the photoresist is improved by secondary full exposure and resist hardening bake, so that the photoresist shrinks due to its photosensitive and thermal characteristics, and the profile forms a hemispherical morphology. At this point, the photolithography process is completed, followed by ICP dry etching, which is an ion etching dominated by chemical etching. Then, based on the photolithographic hemispherical morphology, a certain SiO₂ etching time is set according to the actual deposited SiO₂ thickness to obtain the remaining etching margin. At this point, the microlens 140 appearance similar to that shown in FIG. 1 can be formed. Due to the relatively stable etching rate and strong controllability of SiO₂, the desired etching depth can be achieved by setting the etching time, where the position of the microlens 140 is photolithographed to form a hemispherical SiO₂ morphology, the spherical height herein refers to the height of the hemispherical SiO₂, which is generally between 1.5 and 1.8 μm. Similarly, the spherical width is the diameter width of the arc-shaped hemispherical shape, the height from below the spherical height to the upper bottom of the pixel point is the height of the lower spacer, and the curvature radius can be interpreted as the degree of curvature of the SiO₂ hemispherical curve, the larger the curvature radius, the larger the circle it represents, and the flatter the curve, the smaller the curvature radius, the smaller the circle it represents, and the more curved the curve, and the greater the curvature.

However, through data simulation and multiple experimental verifications, the inventor discovered that the smaller curvature radius, i.e., increasing the spherical width of microlens 140, which is beneficial for light emission, correspondingly, increasing the spherical height, i.e., changing the original spherical height of the hemispherical microlens 140, which also allows escaping light to be emitted from the microlens 140, and by changing the curvature, the total emission angle of the microlens 140 is increased, making it less prone to form total internal reflection, which is beneficial for light emission effect; furthermore, to achieve uniform photolithographic patterns, the photoresist is typically not too thick, because the photoresist is also consumed as a mask layer during the etching process, and both excessive and insufficient etching fail to achieve the ideal spherical height for the microlens 140. When the spherical width and the spherical height can form a semi-circular shape, i.e., when twice the spherical height equals the spherical width, the effect is optimal.

After further research, the inventor found that the remaining amount of the lower spacer also affects the light output effect. For the same spherical height and width, the lower spacer generally does not exceed the height of the spherical height. Under current processes, micro-gap defects exist on both sides of the SiO₂ in the spacer, and the light sources tend to diffuse reflection herein. If the photolithography dimensions of the microlens 140 are adjusted, this defect can be eliminated or reduced during the previous step of etching the microlens 140, the subsequent defect repair effect can be achieved through secondary SiO₂ deposition.

However, in existing process steps, after etching, it is inevitable that the spherical width and height of the microlens 140 are not in an optimal state. For example, the SiO₂ film layer of the microlens 140 is first deposited by PECVD with a thickness of approximately 2.5-3.5 micrometers. Subsequently, by adjusting the photolithography morphology of the microlens 140, such as resist thickness, exposure energy, and film hardening temperature, the photolithography array morphology at the corresponding pixel locations is obtained, and the passivation protection layer SiO₂ material of the micro lens 140 is ion etched to form a hemispherical SiO₂ microlens 140 with a lens-like morphology. After the SiO₂ etching of the microlens 140 is completed, due to the lithographic dimensions and ion etching of the microlens 140, the curvature radius, lower spacer height, spherical height, and lens spherical width of the overall microlens 140 are slightly smaller, therefore, a secondary SiO₂ deposition is performed on the microlens 140 to increase the curvature radius, lower spacer height, spherical height, and lens spherical width of the microlens 140. The thickness of the secondary SiO₂ deposition film needs to be determined according to the thickness of the SiO₂ film deposited by the previous step of microlens 140 and the etching morphology of the microlens 140, the secondary deposition typically is 0.2 to 1 micrometer, which can be carried out in a single or multiple deposition steps. Through research, the inventors discovered that secondary deposition can achieve better brightness enhancement effects.

Based on this, the present disclosure provides a micro-LED chip and the method for manufacturing the same. By forming the microlens 140 through multiple deposition methods, the lower spacer height, curvature radius, and lens spherical height of the microlens 140 are adjusted, which mitigates lens micro-defects and effectively enhances the luminous efficiency of the micro-LED chip.

In the embodiments of the present disclosure, the first bottom contact hole 111 is electrically connected with the first type semiconductor layer 121 of the micro-mesa 120 through the bottom metal layer 130 and the bottom conductive layer 150; and the second bottom contact structure 112 is electrically connected with the second type semiconductor layer 122 of the micro-mesa 120 through the top conductive layer 170. The first bottom contact hole 111 and the second bottom contact structure 112, serving as the positive and negative electrodes of the micro-LED, are both disposed within the bottom dielectric layer 113 below the micro-mesa. The bottom dielectric layer 113 is located on the top surface of the drive backplane 110. The first bottom contact hole 111 is electrically connected with the drive circuit within the drive backplane 110, and the second bottom contact structure 112 is led out from the edge of the micro-mesa array and electrically connected with external pads. Embedding the second bottom contact structure 112 as the top electrode of the micro-LED within the bottom dielectric layer 113 of the drive backplane 110 can prevent the second bottom contact structure 112 from obstructing the micro-mesa, thereby increasing light extraction efficiency. Furthermore, the structure proposed by the present disclosure eliminates the arrangement of the top electrode on the side surface of the micro-mesa, and the beam collimation effect of the microlens is better.

In some embodiments, the top of the second type semiconductor layer 122 further includes a metal island layer 180. The metal island layer 180 includes multiple mutually isolated metal particles.

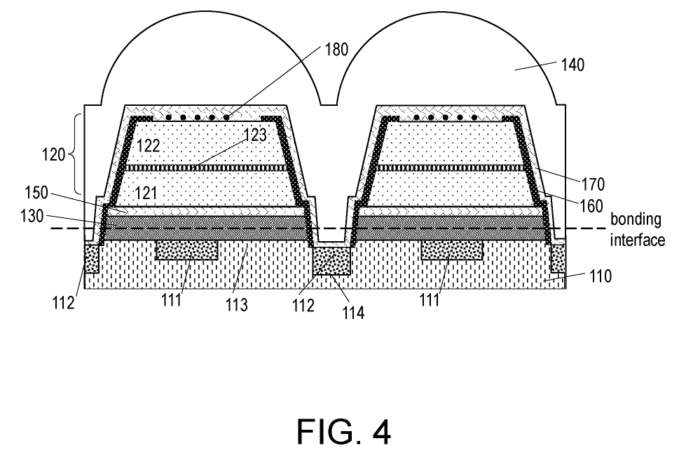

In some embodiments, the second bottom contact structure 112, serving as the top electrode of the micro-LED, is embedded within the bottom dielectric layer 113 of the drive backplane 110. In order to avoid short circuiting of the positive and negative electrodes of the micro-LED caused by contact between the second bottom contact structure 112 and the bottom metal layer 130, the top of the second bottom contact structure 112 may be designed to be lower than the bottom of the bottom metal layer 130. FIG. 4 illustrates a schematic longitudinal sectional view of a micro-LED chip according to an embodiment of the present disclosure. As shown in FIG. 4, the top of the second bottom contact structure 112 is lower than the top of the trench 114 in which it is located. Consequently, the second bottom contact structure 112 is spaced apart from the bottom metal layer 130 in the vertical direction.

In some embodiments, the second bottom contact structure 112 may be further spaced apart from the bottom metal layer 130 in the horizontal direction. For example, the top of the trench 114 where the second bottom contact structure 112 is located can be widened, so that the spacing between the sidewalls of the trench 114 located above the second bottom contact structure 112 is greater than the spacing between the sidewalls of the trench 114 in contact with the second bottom contact structure 112.

In some embodiments, an upper connection portion (not shown in the figure) exists between the top conductive layer 170 and the top surface of the second type semiconductor layer 122, and this upper connection portion is electrically connected with the top conductive layer 170 and the second type semiconductor layer 122. The material of the upper connection portion may be metal, and this metal may include one or more of the following: aluminum (Al), gold (Au), rhodium (Rh), silver (Ag), chromium (Cr), titanium (Ti), platinum (Pt), tin (Sn), copper (Cu), gold-tin alloy (AuSn), titanium-tungsten alloy (TiW), etc. Alternatively, the material of the upper connection portion may be a conductive transparent electrode, such as indium tin oxide (ITO) or fluorine-doped tin oxide (FTO).

In some embodiments, the micro-mesa 120 may further include a lower connection portion (not shown in the figure) located between the bottom conductive layer 150 and the bottom surface of the first type semiconductor layer 121, and the lower connection portion is electrically connected with the bottom conductive layer 150 and the first type semiconductor layer 121. The material of the lower connection portion is metal, including one or more of aluminum (Al), gold (Au), rhodium (Rh), silver (Ag), chromium (Cr), titanium (Ti), platinum (Pt), tin (Sn), copper (Cu), gold-tin alloy (AuSn), titanium-tungsten alloy (TiW), etc.

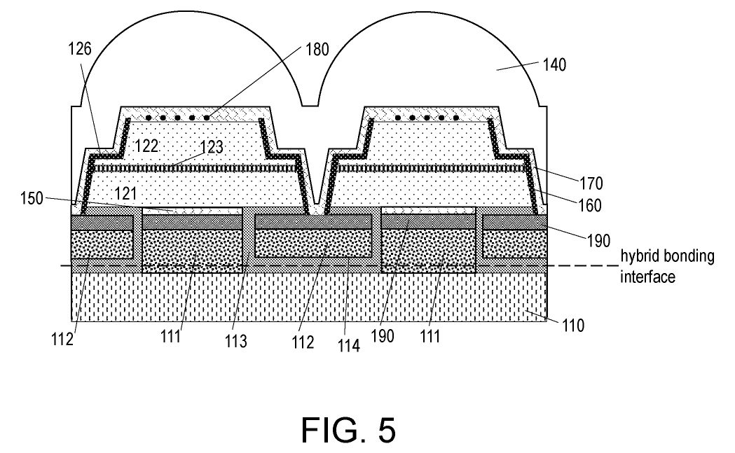

FIG. 5 illustrates a schematic longitudinal sectional view of a micro-LED chip according to an embodiment of the present disclosure. The difference between the micro-LED chip shown in FIG. 5 and the micro-LED chip shown in FIG. 2 lies in: the micro-LED chip shown in FIG. 5 is bonded to the drive backplane 110 through hybrid bonding technology. As shown in FIG. 5, in some embodiments, the bottom dielectric layer 113 is located at the bottom of the micro-mesa, and the micro-mesa is bonded to the drive backplane 110 through the bottom dielectric layer 113 and the first bottom contact hole 111. For the drive backplane 110 and the LED structure on two sides of the bonding interface, the surface of the bottom dielectric layer 113 is flush with the surface of the first bottom contact hole 111. During bonding, the drive backplane 110 and the LED structure are aligned, and the bottom dielectric layer portion of the drive backplane 110 is bonded to the bottom dielectric layer portion of the LED structure, and the first bottom contact hole portion of the drive backplane 110 is bonded to the first bottom contact hole of the LED structure, thereby achieving hybrid bonding. In some embodiments, the first bottom contact hole 111 may include gold-gold bonding, gold-tin bonding, gold-indium bonding, titanium-titanium bonding, copper-copper bonding, or combinations of them. For example, if gold-gold bonding is selected, two layers of gold require a chromium coating as an adhesive layer and a platinum coating as an anti-diffusion layer. And the platinum coating is located between the gold layer and the chromium layer. The chromium layer and platinum layer are located at the top and bottom of the two bonding gold layers, respectively. In some embodiments, when the thicknesses of the two layers of gold are substantially the same, under high pressure and high temperature conditions, the mutual diffusion between the two layers of gold will bind the two layers together. Eutectic bonding, hot-press bonding, and transient liquid phase (TLP) bonding are all exemplary technologies that may be used. The composition material of the bottom dielectric layer 113 may be silicon dioxide (SiO₂).

As shown in FIG. 5, the second bottom contact structure 112 is located in the bottom dielectric layer 113 between adjacent micro-mesas and does not contact the first type semiconductor layer 121.

In some embodiments, as shown in FIG. 5, the micro-LED structure further includes a reflective layer 190. The reflective layer 190 is located between the bottom conductive layer 150 and the first bottom contact hole 111, as well as between the second bottom contact structure 112 and the top conductive layer 170. The top area of the reflective layer 190 may substantially be the same as the first bottom contact hole 111 and the second bottom contact structure 112. The reflective layer 190 may be a metal layer having high reflectivity, and this metal layer includes one or more metals, such as platinum (Pt), rhodium (Rh), aluminum (Al), gold (Au), and silver (Ag). The reflective layer 190 may also be a stacked distributed Bragg reflector (DBR) layer including titanium dioxide (TiO₂)/silicon dioxide (SiO₂); or any other layer having total internal reflection properties, including multilayer omnidirectional reflectors (ODR); or a combination of the above situations. The reflective layer 190 can reflect light emitted from the light-emitting area, thereby improving the brightness and luminous efficiency of the micro-LED panel or display. For example, light emitted from the light-emitting area may reach the reflective layer and be reflected upward by these reflective layers.

As shown in FIG. 5, the sidewall of the micro-mesa is provided with a step 126. Specifically, the step 126 includes a flat portion located on the sidewall of the second type semiconductor layer 122. At this flat portion, the transverse dimensions of the second type semiconductor layer 122 decrease by a specific distance from the edge toward the center, so that the flat portion located on the sidewall of the second type semiconductor layer 122 is formed. By forming the step 126, the top area of the second type semiconductor layer 122 is reduced, and the electron and hole recombination area at the light-emitting layer 123 converges toward the center of the light-emitting mesa. The test results demonstrate that the micro light-emitting diode with step on sidewall exhibits a significant enhancement in light intensity within a small light-emitting angle range.

In some embodiments, the micro-LED chip may include red, blue, and/or green micro-LEDs. In some embodiments, the pitch of the micro-LED array, i.e., the minimum center-to-center distance between micro-LEDs, may be between approximately 2 micrometers and approximately 50 micrometers. In some embodiments, the number of pixels on the micro-LED chip may be between thousands and millions.

Although the various embodiments of the present disclosure have been described above, it should be understood that they are presented only as examples and not as limitations. It will be apparent to those skilled in the art that various combinations, variations and changes can be made thereto without departing from the spirit and scope of the present disclosure. Therefore, the width and scope of the present disclosure disclosed herein should not be limited by the exemplary embodiments disclosed above, but should only be defined based on the accompanying claims and their equivalents.

What is claimed is:

1. A micro-LED chip, comprising:
a micro-mesa array comprising a plurality of micro-mesas, wherein each micro-mesa comprises, from bottom to top, a first type semiconductor layer, a light-emitting layer, and a second type semiconductor layer stacked in sequence, wherein the first type semiconductor layer is different from the second type semiconductor layer;
a bottom metal layer located under at least one micro-mesa;
a bottom dielectric layer located under the bottom metal layer, wherein the bottom dielectric layer is provided with at least one trench;
a first bottom contact hole located in the bottom dielectric layer and being in contact with a bottom of the bottom metal layer;
a sidewall dielectric layer located on a sidewall of the micro-mesa and a sidewall of the bottom metal layer;
a top conductive layer continuously covering a top surface of the micro-mesa, a surface of the sidewall dielectric layer, and a region between adjacent micro-mesas; and
a second bottom contact structure located in the at least one trench and within the bottom dielectric layer between adjacent micro-mesas, the second bottom contact structure being not in contact with the bottom metal layer.

2. The micro-LED chip according to claim 1, wherein a top of the second bottom contact structure is lower than the bottom of the bottom metal layer, and the top of the second bottom contact structure is lower than a top of the trench.

3. The micro-LED chip according to claim 1, wherein a transverse width of the second bottom contact structure is less than a transverse width of a gap between adjacent bottom metal layers.

4. The micro-LED chip according to claim 1, wherein the top conductive layer further covers a top surface of the second bottom contact structure.

5. The micro-LED chip according to claim 1, wherein a plurality of the second bottom contact structures are integrally connected with each other.

6. The micro-LED chip according to claim 5, wherein the plurality of second bottom contact structures are arranged in a crisscross interconnected pattern and disposed around the first bottom contact hole below each micro-mesa, the at least one trench is also arranged in a crisscross interconnected pattern and disposed in the bottom dielectric layer and located around the first bottom contact hole below each micro-mesa.

7. The micro-LED chip according to claim 6, wherein the top conductive layer contacts a top surface of the second bottom contact structure at least at one crisscross intersection of the second bottom contact structures.

8. The micro-LED chip according to claim 5, wherein the first bottom contact hole and the second bottom contact structure are arranged at intervals.

9. The micro-LED chip according to claim 2, wherein a spacing between sidewalls of the trench located above the second bottom contact structure is greater than the spacing between the sidewalls of the trench in contact with the second bottom contact structure.

10. The micro-LED chip according to claim 1, wherein a material of the first bottom contact hole is metal; a material of the second bottom contact structure is metal.

11. The micro-LED chip according to claim 10, wherein the metal comprises one or more of copper, gold, tin, platinum, tungsten, chromium, rhodium, titanium, silver, germanium, or nickel.

12. The micro-LED chip according to claim 1, wherein the sidewall dielectric layer covers the entire sidewall of the micro-mesa and covers the entire sidewall of the bottom metal layer, leaving an aperture at a top of the micro-mesa; and the aperture exposes part or all of the top of the micro-mesa.

13. The micro-LED chip according to claim 12, wherein a material of the sidewall dielectric layer is one or more of silicon oxide, silicon oxynitride, or silicon nitride.

14. The micro-LED chip according to claim 1, wherein the bottom of the first type semiconductor layer also has a bottom conductive layer; the bottom metal layer is located at a bottom of the bottom conductive layer; the light-emitting layer is a multilayer stack; the first type semiconductor layer is N-type and the second type semiconductor layer is P-type; or, the first type semiconductor layer is P-type and the second type semiconductor layer is N-type.

15. The micro-LED chip according to claim 14, further comprising a reflective layer, wherein the reflective layer is located between the bottom conductive layer and the first bottom contact hole, and located between the second bottom contact structure and the top conductive layer, respectively, and a top area of the reflective layer is substantially the same as a top area of the first bottom contact hole and the second bottom contact structure.

16. The micro-LED chip according to claim 14, wherein a material of the bottom metal layer is one or more of the following metals or an alloy thereof: Cr, Al, Ti, Ni, Pt, Au, or Sn;
a material of the bottom conductive layer is one or a combination of graphene, indium tin oxide, aluminum-doped zinc oxide, or fluorine-doped tin oxide; and
a material of the top conductive layer is one or a combination of graphene, indium tin oxide, aluminum-doped zinc oxide, or fluorine-doped tin oxide.

17. The micro-LED chip according to claim 1, wherein a top of the second type semiconductor layer comprises a metal island layer; and the metal island layer comprises a plurality of mutually isolated metal particles.

18. The micro-LED chip according to claim 1, further comprising a drive backplane, wherein the drive backplane comprises at least one drive circuit, and the at least one drive circuit is electrically connected with each first bottom contact hole in the micro-mesa array.

19. The micro-LED chip according to claim 1, wherein the sidewall of the micro-mesa is provided with a step, and the step comprises a flat portion located on a sidewall of the second type semiconductor layer.

20. The micro-LED chip according to claim 1, wherein the sidewall of the micro-mesa is inclined, with an inclination angle range of 60° to 85°.
